(19) United States
(12) Patent Application Publication
(10) Pub. No.: US 2022/0043432 A1
(43) Pub. Date: Feb. 10, 2022

(54) SYSTEM FOR DETECTING SEMICONDUCTOR PROCESS AND METHOD FOR DETECTING SEMICONDUCTOR PROCESS

(71) Applicant: CHANGXIN MEMORY TECHNOLOGIES, INC., Hefei (CN)

(72) Inventors: HUAN-CHENG LI, Hefei (CN); Yong-Yu CHEN, Hefei (CN)

(21) Appl. No.: 17/400,577

(22) Filed: Aug. 12, 2021

Related U.S. Application Data
(63) Continuation of application No. PCT/CN2021/099428, filed on Jun. 10, 2021.

(30) Foreign Application Priority Data
Aug. 6, 2020 (CN) 202010785550.4

(51) Int. Cl. G05B 19/418

(52) U.S. Cl. CPC G05B 19/41835; G05B 2219/45031; G05B 19/4183

(57) ABSTRACT

A system for detecting a semiconductor process and a method for detecting a semiconductor process are provided. The system for detecting a semiconductor process includes a memory for storing computer-executable instructions and a processor for executing the computer-executable instructions to implement functions of a first acquisition module and a matching module. The first acquisition module is configured to acquire a preset process recipe including preset process recipe parameters, and is further configured to initiate a matching request to the matching module and send the preset process recipe to the matching module. The matching module is configured to acquire, based on the matching request, a production process recipe including a production process recipe flow and production process recipe parameters, and is further configured to determine whether the production process recipe flow is correct and determine whether the production process recipe parameters meet the preset process recipe parameters.

### CROSS-REFERENCE TO RELATED APPLICATION

The present application is a continuation of International Patent Application No. PCT/CN2021/099428, filed on Jun. 10, 2021, which is based on and claims priority from Chinese patent application No. 202010785550.4, filed on Aug. 6, 2020 and entitled “System for Detecting Semiconductor Process and Method for Detecting Semiconductor Process”, The disclosures of International Patent Application No. PCT/CN2021/099428 and Chinese patent application No. 202010785550.4 are hereby incorporated by reference in their entireties.

### BACKGROUND

In a wafer manufacturing process, different wafer process procedures and corresponding process parameters are involved. The wafer process procedures and the corresponding process parameters are set and regulated through a process recipe. The key to ensuring that a manufactured wafer has a high yield is to verify whether the process recipe is correct.

However, the applicant has found that the verification of the process recipe in the related art only includes the check of the process parameters in the process recipe, which is not comprehensive enough.

### SUMMARY

The present disclosure relates to the field of semiconductors, and in particular to a system for detecting a semiconductor process and a method for detecting a semiconductor process.

An embodiment of the present disclosure provides a system for detecting a semiconductor process. The system for detecting a semiconductor process may include a first acquisition module and a matching module. The first acquisition module may be configured to acquire a preset process recipe including preset process recipe parameters, and may be further configured to initiate a matching request to the matching module and send the preset process recipe to the matching module. The matching module may be configured to acquire, based on the matching request, a production process recipe including a production process recipe flow and production process recipe parameters, and may be further configured to determine whether the production process recipe flow is correct and determine whether the production process recipe parameters meet the preset process recipe parameters.

An embodiment of the present disclosure also provides a method for detecting a semiconductor process. The method for detecting a semiconductor process may include: acquiring a preset process recipe including preset process recipe parameters; acquiring a production process recipe including a production process recipe flow and production process recipe parameters; and determining whether the production process recipe flow is correct, and determining whether the production process recipe parameters meet the preset process recipe parameters.

An embodiment of the present disclosure also provides a non-transitory storage medium having stored thereon instructions that when executed by a processor, implement a method for detecting a semiconductor process, the method including: acquiring a preset process recipe comprising preset process recipe parameters; acquiring a production process recipe comprising a production process recipe flow and production process recipe parameters; and determining whether the production process recipe flow is correct, and determining whether the production process recipe parameters meet the preset process recipe parameters.

### BRIEF DESCRIPTION OF THE DRAWINGS

FIG. 1 is a schematic structure diagram of a system for detecting a semiconductor process according to an embodiment of the present disclosure.

FIGS. 2 to 4 are schematic diagrams of a production process recipe flow according to an embodiment of the present disclosure.

FIG. 5 is a schematic structure diagram of a system for detecting a semiconductor process according to another embodiment of the present disclosure.

FIG. 6 is a schematic structure diagram of a system for detecting a semiconductor process according to another embodiment of the present disclosure.

FIG. 7 is a schematic flowchart of a method for detecting a semiconductor process according to yet another embodiment of the present disclosure.

### DETAILED DESCRIPTION

At present, the verification of a process recipe only includes the check of process parameters in the process recipe, which is not comprehensive enough.

In order to solve the above-described problem, an embodiment of the present disclosure provides a system for detecting a semiconductor process. The system for detecting a semiconductor process includes a first acquisition module and a matching module. The first acquisition module is configured to acquire a preset process recipe including preset process recipe parameters, and is further configured to initiate a matching request to the matching module and send the preset process recipe to the matching module. The matching module is configured to acquire, based on the matching request, a production process recipe including a production process recipe flow and production process recipe parameters, and is further configured to determine whether the production process recipe flow is correct and determine whether the production process recipe parameters meet the preset process recipe parameters.

To more clarify the objects, technical solutions, and advantages of the embodiments of the present disclosure, various embodiments of the present disclosure will be described below in combination with the accompanying drawings. However, those skilled in the art will appreciate that in various embodiments of the present disclosure, numerous technical details are set forth in order to provide readers with a better understanding of the present disclosure. However, even without these technical details and various changes and modifications based on the following embodiments, the claimed technical solution of the present disclosure may be implemented. The following divisions of the various embodiments are for convenience of description and should not be construed as limiting specific implementations of the present disclosure, and the various embodiments may be combined and cited with each other without contradiction.

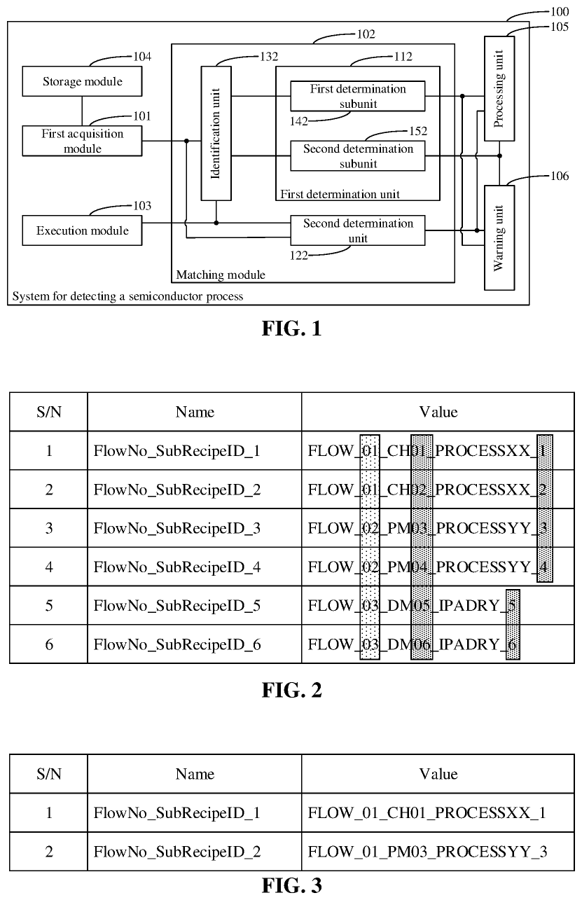

FIG. 1 is a schematic structure diagram of a system for detecting a semiconductor process according to an embodiment of the present disclosure. Hereinafter, the system for detecting a semiconductor process of the present embodiment will be described in detail.

Referring to FIG. 1, the system for detecting a semiconductor process 100 includes a first acquisition module 101 and a matching module 102.

The first acquisition module 101 is connected to the matching module 102 for acquiring a preset process recipe including preset process recipe parameters. The first acquisition module 101 is further configured to initiate a matching request to the matching module 102 and send the preset process recipe to the matching module 102. The preset process recipe is a stored standard process recipe.

In the present embodiment, the system for detecting a semiconductor process 100 further includes: a storage module 104, which is connected to the first acquisition module 101 and stores a plurality of preset process recipes. The first acquisition module 101 is configured to acquire the preset process recipe from the storage module 104.

In an example, the first acquisition module 101 and the storage module 104 are implemented by a Recipe Management System (RMS) that stores a plurality of preset process recipes. The production process recipe is detected as needed, and the corresponding preset process recipe is acquired for checking.

The matching module 102 is connected to the first acquisition module 101 for acquiring, based on the matching request, a production process recipe including a production process recipe flow and production process recipe parameters. The matching module 102 is further configured to determine whether the production process recipe flow is correct and determine whether the production process recipe parameters meet the preset process recipe parameters. The production process recipe is used as an indication to perform a designed process procedure.

In an example, the matching module 102 is implemented by an Equipment Automation Program (EAP) for acquiring a preset process recipe and a production process recipe and for detecting the preset process recipe and the production process recipe.

In the present embodiment, the system for detecting a semiconductor process 100 further includes an execution module 103, which is connected to the matching module 102 and configured to upload the production process recipe to the matching module 102. Specifically, the matching module 102 initiates a detection request to the execution module 103 based on the matching request. The execution module 103 is configured to return the production process recipe to the matching module 102 based on the detection request.

In an example, the execution module 103 is implemented by an EQP having an input end for related process operators to input a production process recipe.

Specifically, the matching module 102 includes a first determination unit 112 and a second determination unit 122. The first determination unit 112 is connected to the first acquisition module 101 for determining whether the production process recipe parameters meet the preset process recipe parameters. The second determination unit 122 is connected to the first acquisition module 101 for determining whether the production process recipe flow is correct.

In an example, the second determination unit 122 is configured to determine whether the production process recipe parameters meet the preset process recipe parameters. A preset parameter range is acquired for the preset process recipe parameters according to optimal process recipe parameters and a parameter fluctuation range. If the production process recipe parameters are in the preset parameter range, it is determined that the production process recipe parameters meet the preset process recipe parameters. If the production process recipe parameters are not in the preset parameter range, it is determined that the production process recipe parameters do not meet the preset process recipe parameters.

Referring to FIGS. 2-5, in the present embodiment, the determination of the correctness of the process recipe flow is implemented by a process flow number, a path name, and a path serial number contained in a single step.

Specifically, in the present embodiment, the matching module 102 further includes an identification unit 132. The first determination unit 112 and the second determination unit 122 are connected to the first acquisition module 101 through the identification unit 132 for identifying a production flow serial number, a path name, and a path serial number, which are contained in each single step in the production process recipe flow. The production flow serial number is used for indicating an execution sequence of the single step. The path name is used for indicating an execution purpose of the single step. The path serial number is used for indicating an execution object of the single step.

Compared with the related art, the production process recipe parameters in the production process recipe are verified through the process recipe parameters in the preset process recipe to realize the verification of the process parameters. Moreover, the production process recipe flow is checked to realize the verification of the process flow. A more comprehensive checking mode ensures that a manufactured wafer has a high yield.

Referring to FIG. 2, an entire table shows a production process recipe flow. Name is used for indicating a name of each single step in the production process recipe. A production process number, a path name, and a path serial number are respectively represented through specific fields contained in a single step. Taking FlowNo_SubRecipeID_1 as an example, FLOW_01 is used for representing a production flow sequence. 01 in FLOW_01 is a production flow serial number. Numeric items 01 and 1 in CH01_PROCESSXX_1 are used for representing path serial numbers, i.e. execution objects of a single step. An alphabetic item CH_PROCESSXX is used for representing a path name, i.e. an execution purpose of a single step.

The first determination unit 112 is configured to determine whether the production process recipe flow is correct through the production flow serial number, the path name, and the path serial number, which are contained in each single step in the production process recipe flow.

Specifically, in the present embodiment, the first determination unit 112 includes a first determination subunit 142 and a second determination subunit 152.

The first determination subunit 142 is connected to the identification unit 132 for determining whether a single step is repeatedly processed or missed in the production process recipe flow based on the execution sequence of each single step in the production process recipe flow. The execution sequence of the single steps includes: alternatively executing the single steps with the same production flow serial number in the production process recipe flow, and sequentially executing the single steps with different production flow serial numbers in the production process recipe flow according to a sequence of the production flow serial numbers. Referring to FIG. 2, a single step 1 and a single step 2 are executed alternatively, a single step 3 and a single step 4 are executed alternatively, and a single step 5 and a single step 6 are executed alternatively. The single step 1, the single step 3, and the single step 5 are executed sequentially. The single step 2, the single step 4, and the single step 6 are executed sequentially.

The second determination subunit 152 is connected to the identification unit 132 for determining whether a single step is repeatedly processed or missed in the production process recipe flow. The operation of determining whether a single step is repeatedly processed or missed in the production process recipe flow includes the following operations. When the single steps with different path names exist in the single steps with the same production flow serial number, a single step is missed. When the single steps with the same path name exist in the single steps with different production flow serial numbers, a single step is repeatedly processed. Referring to FIG. 2, the single step 1 and the single step 2 are the same single step, but execution objects are different. The single step 3 and the single step 4 are the same single step, but execution objects are different. The single step 5 and the single step 6 are the same single step, but execution objects are different. The single step 1, the single step 3, and the single step 5 are different single steps. The single step 2, the single step 4, and the single step 6 are different single steps.

Referring to FIG. 3, two single steps shown in FIG. 3 have the same production flow serial number, which indicates that the two single steps are alternatively executed. But the two single steps have different path names, which indicates that the two single steps have different execution purposes. On the premise that the execution purposes are different, the execution objects are necessarily different, i.e. the corresponding path serial numbers are different, which indicates that the two single steps represent different steps, but have an alternative execution relationship. While one of the single steps is executed, the other single step will be skipped, which indicates that a single step of missing processing exists due to setting errors of the current process recipe flow.

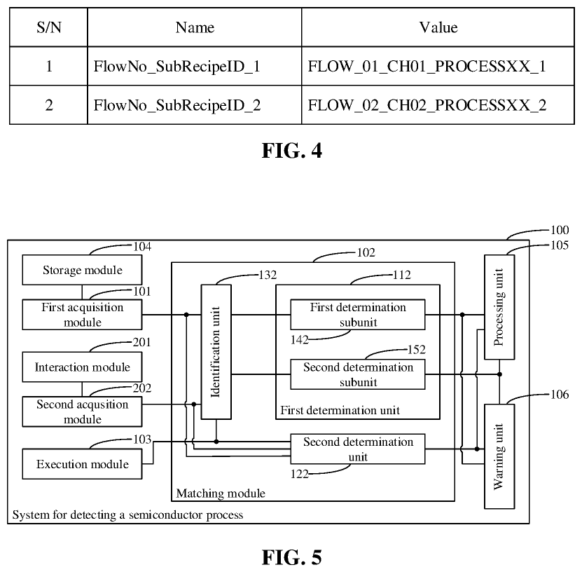

Referring to FIG. 4, two single steps shown in FIG. 4 have different production flow serial numbers, which indicates that the two single steps are sequentially executed. But the two single steps have the same path name, which indicates that the two single steps have the same execution purpose. Execution objects are different, i.e. the corresponding path serial numbers are different, and the same step is executed through the different execution objects, which indicates that the two single steps represent the same step, but have a sequential execution relationship. The above-described two single steps may be sequentially executed, which indicates that a single step of repeated processing exists due to setting errors of the current process recipe flow.

In addition, in the present embodiment, a processing unit 105 connected to the first determination unit 112 and the second determination unit 122 is further included. The processing unit is configured to suspend use of the process recipe flow when the production process recipe flow is incorrect or the production process recipe parameters do not meet the preset process recipe parameters. The processing unit 105 stops the use of a wrong process recipe in time, so that the production of substandard wafers is avoided, and the cost problem of a wafer process is solved.

In addition, in the present embodiment, a warning unit 106 connected to the first determination unit 112 and the second determination unit 122 is further included. The processing unit is configured to send early warning information when the production process recipe flow is incorrect or the production process recipe parameters do not meet the preset process recipe parameters. When the configuration of the process recipe is wrong, related engineers are informed in time to check through the warning unit 106, so that the efficiency of wafer production is ensured.

Compared with the related art, the matching module verifies the production process recipe parameters in the production process recipe for the process recipe parameters in the preset process recipe to realize the verification of the process parameters. Moreover, the matching module checks the production process recipe flow to realize the verification of the process flow. A more comprehensive checking mode ensures that a manufactured wafer has a high yield.

It is to be noted that each module referred to in the present embodiment is a logical module. In practical application, a logical unit may be a physical unit or a part of a physical unit, or may be implemented with a combination of physical units. In addition, in order to highlight the innovative portion of the present disclosure, units not closely related to solving the technical problems set forth in the present disclosure have not been introduced in the present embodiment, but this does not indicate that other units are not present in the present embodiment.

Another embodiment of the present disclosure relates to a system for detecting a semiconductor process. Unlike the previous embodiment in which the preset process recipe and the production process recipe are detected, the present embodiment detects a new process recipe and a pre-production process recipe for determining whether the newly designed process recipe is applicable.

FIG. 5 is a schematic structure diagram of a system for detecting a semiconductor process according to an embodiment of the present disclosure. Hereinafter, the system for detecting a semiconductor process of the present embodiment will be described in detail.

Referring to FIG. 5, based on the above-described embodiment, the system for detecting a semiconductor process 100 further includes a second acquisition module 202, which is connected to the matching module 102 for acquiring a new process recipe, initiating a matching request to the matching module 102, and sending the new process recipe to the matching module 102. The new process recipe is a newly designed process recipe. The new process recipe includes new process recipe parameters and a new process recipe flow.

In an example, the second acquisition module 202 is implemented by an RMS to acquire a new process recipe newly written by related engineers.

In the present embodiment, the system for detecting a semiconductor process 100 further includes: an interaction module 201, which is connected to the second acquisition module 202 for inputting a new process recipe. The second acquisition module 202 is configured to acquire the new process recipe from the interaction module 201.

In an example, the interaction module 201 is implemented by an input end (hereinafter referred to as RMS-C) in the RMS.

The matching module 102 is configured to acquire, based on the matching request, a pre-production process recipe including pre-production process recipe parameters, and further configured to determine whether the new process recipe flow is correct and determine whether the new process recipe parameters meet the pre-production process recipe parameters. The pre-production process recipe is used as an indication to perform a newly designed process procedure.

Specifically, the first determination unit 112 is further connected to the second acquisition module 202 for determining whether the new process recipe parameters meet the pre-production process recipe parameters. The second determination unit is further connected to the second acquisition module 202 for determining whether the new process recipe flow is correct.

In an example, the second determination unit 122 is configured to determine whether the new process recipe parameters meet the pre-production process recipe parameters. A preset parameter range is acquired for the pre-production process recipe parameters according to optimal process recipe parameters and a parameter fluctuation range. If the new process recipe parameters are in the preset parameter range, it is determined that the new process recipe parameters meet the pre-production process recipe parameters. If the new process recipe parameters are not in the preset parameter range, it is determined that the new process recipe parameters do not meet the pre-production process recipe parameters.

In the present embodiment, the determination of the correctness of the new recipe flow is implemented by a new flow number, a path name, and a path serial number contained in a single step.

Specifically, in the present embodiment, the matching module 102 further includes an identification unit 132. The first determination unit 112 and the second determination unit 122 are connected to the second acquisition module 202 through the identification unit 132 for identifying a new flow number, a path name, and a path serial number, which are contained in each single step in the new process recipe flow. The new flow number is used for indicating an execution sequence of the single step. The path name is used for indicating an execution purpose of the single step. The path serial number is used for indicating an execution object of the single step.

Specifically, in the present embodiment, the first determination unit 112 includes a first determination subunit 142 and a second determination subunit 152.

The first determination subunit 142 is connected to the identification unit 132 for determining whether a single step of repeated processing or missing processing exists in the new process recipe flow based on the execution sequence of each single step in the new process recipe flow. The execution sequence of the single steps includes: alternatively executing the single steps with the same new flow number in the new process recipe flow, and sequentially executing the single steps with different new flow numbers in the production process recipe flow according to a sequence of the new flow numbers.

The second determination subunit 152 is connected to the identification unit 132 for determining whether a single step is repeatedly processed or missed in the production process recipe flow. The operation of determining whether a single step of repeated processing or missing processing exists in the new process recipe flow includes the following operations. When the single steps with different path names exist in the single steps with the same new flow number, a single step is missed. When the single steps with the same path name exist in the single steps with different new flow numbers, a single step is repeatedly processed.

In the present embodiment, the matching module 102 is further configured to return determination results of the new process recipe and the pre-production process recipe to the interaction module 201. The interaction module 201 is further configured to display the determination results.

Compared with the related art, the new process recipe is checked to acquire a better new process recipe and improve the yield of wafer production.

It is to be noted that each module referred to in the present embodiment is a logical module. In practical application, a logical unit may be a physical unit or a part of a physical unit, or may be implemented with a combination of physical units. In addition, in order to highlight the innovative portion of the present disclosure, units not closely related to solving the technical problems set forth in the present disclosure have not been introduced in the present embodiment, but this does not indicate that other units are not present in the present embodiment.

Another embodiment of the present disclosure relates to a system for detecting a semiconductor process. Unlike the above-described embodiment, the present embodiment detects the new process recipe and the pre-production process recipe firstly. The new process recipe is suitable for on-line process use by default, and the new process recipe is directly put into on-line use, i.e. matching detection with the production process recipe is carried out.

FIG. 6 is a schematic structure diagram of a system for detecting a semiconductor process according to an embodiment of the present disclosure. Hereinafter, the system for detecting a semiconductor process of the present embodiment will be described in detail.

Based on the previous embodiment, in the present embodiment, the interaction module 201 is further connected to the storage module 104. The first acquisition module 101 is further configured to acquire the new process recipe as the preset process recipe when the new process recipe conforms to the pre-production process recipe.

Specifically, after learning from the determination results that the new process recipe conforms to the pre-production process recipe, the interaction module 201 stores the new process recipe at the preset process recipe in the storage module 104. The first acquisition module 101 acquires the above-described new process recipe from the storage module 104. That is, the newly written new process recipe has been detected firstly. When the new process recipe is reasonably designed, the new process recipe is used as the production process recipe, and is secondarily detected during use.

Compared with the related art, the new process recipe is checked to acquire a better new process recipe, thereby improving the yield of wafer production. When the new process recipe is used, the matching module verifies the production process recipe parameters in the production process recipe for the process recipe parameters in the new process recipe to realize the verification of the process parameters. Moreover, the matching module checks the production process recipe flow to realize the verification of the process flow. A more comprehensive checking mode ensures that a manufactured wafer has a high yield.

It is to be noted that each module referred to in the present embodiment is a logical module. In practical application, a logical unit may be a physical unit or a part of a physical unit, or may be implemented with a combination of physical units. In addition, in order to highlight the innovative portion of the present disclosure, units not closely related to solving the technical problems set forth in the present disclosure have not been introduced in the present embodiment, but this does not indicate that other units are not present in the present embodiment.

Yet another embodiment of the present disclosure relates to a method for detecting a semiconductor process.

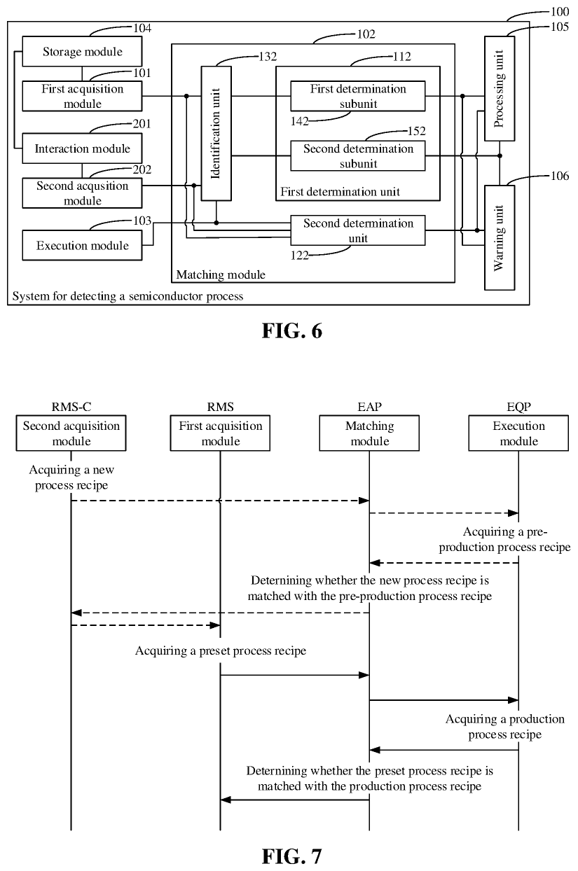

Referring to FIG. 7, the method for detecting a semiconductor process provided by the present embodiment will be described in detail with reference to the accompanying drawings, and descriptions of the same or corresponding parts as those in the above embodiment will be omitted hereinafter.

The method for detecting a semiconductor process includes the following steps. A preset process recipe including preset process recipe parameters is acquired. A production process recipe including a production process recipe flow and production process recipe parameters is acquired. It is determined whether the production process recipe flow is correct and whether the production process recipe parameters meet the preset process recipe parameters.

Referring to FIG. 7, the present embodiment describes a method for specifically detecting a new process recipe as a preset process recipe after checking the new process recipe to acquire a better new process recipe. In other embodiments, the detection may be performed using only the preset process recipe as an actual detection object.

A second acquisition module acquires a preset process recipe including new process recipe parameters. The second acquisition module sends the acquired new process recipe to a matching module. The matching module acquires a pre-production process recipe including pre-production process recipe parameters. The matching module determines whether the new process recipe flow is correct, and determines whether the new process recipe parameters meet the pre-production process recipe parameters.

Specifically, the matching module is configured to determine whether the new process recipe parameters meet the pre-production process recipe parameters. A preset parameter range is acquired for the pre-production process recipe parameters according to optimal process recipe parameters and a parameter fluctuation range. If the new process recipe parameters are in the preset parameter range, it is determined that the new process recipe parameters meet the pre-production process recipe parameters. If the new process recipe parameters are not in the preset parameter range, it is determined that the new process recipe parameters do not meet the pre-production process recipe parameters.

The determination of the correctness of the new process recipe flow is implemented by a new flow number, a path name, and a path serial number contained in a single step. The matching module is configured to identify a new flow number, a path name, and a path serial number, which are contained in each single step in the new process recipe flow. The new flow number is used for indicating an execution sequence of a single step. The path name is used for indicating an execution purpose of a single step. The path serial number is used for indicating an execution object of a single step.

Specifically, the matching module is configured to determine whether a single step of repeated processing or missing processing exists in the new process recipe flow based on the execution sequence of each single step in the new process recipe flow. The execution sequence of the single steps includes: alternatively executing the single steps with the same new flow number in the new process recipe flow, and sequentially executing the single steps with different new flow numbers in the new process recipe flow according to a sequence of the new flow numbers. The matching module is configured to determine whether a single step of repeated processing or missing processing exists in the new process recipe flow. The operation of determining whether a single step of repeated processing or missing processing exists in the new process recipe flow includes the following operations. When the single steps with different path names exist in the single steps with the same new flow number, a single step is missed. When the single steps with the same path name exist in the single steps with different new flow numbers, a single step is repeatedly processed.

After learning from the determination results that the new process recipe conforms to the pre-production process recipe, a first acquisition module acquires the above-described new process recipe. That is, the newly written new process recipe has been detected firstly. When the new process recipe is reasonably designed, the new process recipe is used as the production process recipe, and is secondarily detected during the use of the new process recipe. That is, the new process recipe is taken as the preset process recipe.

The first acquisition module acquires a preset process recipe including preset process recipe parameters. The first acquisition module sends the acquired preset process recipe to the matching module. The matching module acquires a production process recipe including a production process recipe flow and production process recipe parameters, determines whether the production process recipe flow is correct, and determines whether the production process recipe parameters meet the preset process recipe parameters.

Specifically, the matching module is configured to determine whether the production process recipe parameters meet the preset process recipe parameters. A preset parameter range is acquired for the preset process recipe parameters according to optimal process recipe parameters and a parameter fluctuation range. If the production process recipe parameters are in the preset parameter range, it is determined that the production process recipe parameters meet the preset process recipe parameters. If the production process recipe parameters are not in the preset parameter range, it is determined that the production process recipe parameters do not meet the preset process recipe parameters.

The determination of the correctness of the production process recipe flow is implemented by a production flow serial number, a path name, and a path serial number contained in a single step. The matching module is configured to identify a production flow serial number, a path name, and a path serial number, which are contained in each single step in the production process recipe flow. The production flow serial number is used for indicating an execution sequence of a single step. The path name is used for indicating an execution purpose of a single step. The path serial number is used for indicating an execution object of a single step.

Specifically, the matching module is configured to determine whether a single step is repeatedly processed or missed in the production process recipe flow based on the execution sequence of each single step in the production process recipe flow. The execution sequence of the single steps includes: alternatively executing the single steps with the same production flow serial number in the production process recipe flow, and sequentially executing the single steps with different production flow serial numbers in the production process recipe flow according to a sequence of the production flow serial numbers. The matching module is configured to determine whether a single step is repeatedly processed or missed in the production process recipe flow. The operation of determining whether a single step is repeatedly processed or missed in the production process recipe flow includes the following operations. When the single steps with different path names exist in the single steps with the same production flow serial number, a single step is missed. When the single steps with the same path name exist in the single steps with different production flow serial numbers, a single step is repeatedly processed.

Compared with the related art, the production process recipe parameters in the production process recipe are verified through the process recipe parameters in the preset process recipe to realize the verification of the process parameters. Moreover, the production process recipe flow is checked to realize the verification of the process flow. A more comprehensive checking mode ensures that a manufactured wafer has a high yield.

The above division of various steps is merely for clarity of description. During implementation, the steps may be combined into one step or some steps may be split and decomposed into a plurality of steps, which may be within the scope of protection of this patent as long as the same logical relationship is included. It is within the scope of protection of this patent to add insignificant modifications to the process or to introduce insignificant designs without changing the core design of the process.

Since the above-described embodiments correspond to the present embodiment, the present embodiment may be implemented in cooperation with the above-described embodiments. The related technical details mentioned in the above-described embodiments are still valid in the present embodiment, and the technical effects that can be achieved in the above-described embodiments may also be achieved in the present embodiment. Descriptions are omitted here in order to reduce repetition. Accordingly, the related technical details mentioned in the present embodiment may also be applied to the above-described embodiments.

It will be appreciated by those skilled in the art that the various embodiments described above are specific embodiments for implementing the present disclosure and that various changes in form and details may be made in practice without departing from the spirit and scope of the present disclosure.

1. A system for detecting a semiconductor process, comprising a memory for storing computer-executable instructions and a processor for executing the computer-executable instructions to implement functions of a plurality of modules, the plurality of modules comprising:
a first acquisition module, configured to acquire a preset process recipe comprising preset process recipe parameters, wherein
the first acquisition module is further configured to initiate a matching request to a matching module and send the preset process recipe to the matching module; and
the matching module, configured to acquire, based on the matching request, a production process recipe comprising a production process recipe flow and production process recipe parameters, wherein
the matching module is further configured to determine whether the production process recipe flow is correct and determine whether the production process recipe parameters meet the preset process recipe parameters.

2. The system for detecting a semiconductor process of claim 1, wherein the processor is further configured to execute the computer-executable instructions to implement functions of an identification unit and a first determination unit of the matching module, wherein
the identification unit is configured to identify a production flow serial number, a path name, and a path serial number, which are contained in each single step in the production process recipe flow, the production flow serial number being used for indicating an execution sequence of the single step, the path name being used for indicating an execution purpose of the single step, and the path serial number being used for indicating an execution object of the single step; and
the first determination unit is configured to determine whether the production process recipe flow is correct through the production flow serial number, the path name, and the path serial number, which are contained in each single step in the production process recipe flow.

3. The system for detecting a semiconductor process of claim 2, wherein the processor is further configured to execute the computer-executable instructions to implement functions of a first determination subunit of the first determination unit,
the first determination subunit is configured to determine whether a single step is repeatedly processed or missed in the production process recipe flow based on the execution sequence of each single step in the production process recipe flow; and
the execution sequence of the single steps comprises: alternatively executing the single steps with a same production flow serial number in the production process recipe flow, and sequentially executing the single steps with different production flow serial numbers in the production process recipe flow according to a sequence of the production flow serial numbers.

4. The system for detecting a semiconductor process of claim 3, wherein the processor is further configured to execute the computer-executable instructions to implement functions of a second determination subunit of the first determination unit,
the second determination subunit is configured to determine whether a single step is repeatedly processed or missed in the production process recipe flow,
wherein the determining whether a single step is repeatedly processed or missed in the production process recipe flow comprises: when the single steps with different path names exist in the single steps with a same production flow serial number, determining that a single step is missed; and when the single steps with a same path name exist in the single steps with different production flow serial numbers, determining that a single step is repeatedly processed.

5. The system for detecting a semiconductor process of claim 1, wherein the processor is further configured to execute the computer-executable instructions to implement functions of a second determination unit of the matching module, the second determination unit is configured to determine whether the production process recipe parameters meet the preset process recipe parameters.

6. The system for detecting a semiconductor process of claim 1, wherein the memory is further configured to store a plurality of preset process recipes, wherein
the processor is configured to acquire the preset process recipe from the memory.

7. The system for detecting a semiconductor process of claim 1, wherein the processor is further configured to execute the computer-executable instructions to implement functions of an execution module, wherein
the matching module is configured to initiate a detection request to the execution module based on the matching request; and
the execution module is configured to return the production process recipe to the matching module based on the detection request.

8. The system for detecting a semiconductor process of claim 1, wherein the processor is further configured to execute the computer-executable instructions to implement functions of a second acquisition module, configured to acquire a new process recipe, initiate a matching request to the matching module, and send the new process recipe to the matching module, the new process recipe comprising: new process recipe parameters and a new process recipe flow, wherein
the matching module is configured to acquire, based on the matching request, a pre-production process recipe comprising pre-production process recipe parameters; and
the matching module is further configured to determine whether the new process recipe flow is correct and determine whether the new process recipe parameters meet the pre-production process recipe parameters.

9. The system for detecting a semiconductor process of claim 8, wherein the processor is further configured to execute the computer-executable instructions to implement functions of an interaction module, configured to input the new process recipe, wherein
the second acquisition module is configured to acquire the new process recipe from the interaction module.

10. The system for detecting a semiconductor process of claim 9, wherein the matching module is further configured to return determination results of the new process recipe and the pre-production process recipe to the interaction module, and the interaction module is further configured to display the determination results.

11. The system for detecting a semiconductor process of claim 8, wherein the first acquisition module is further configured to acquire the new process recipe as the preset process recipe when the new process recipe conforms to the pre-production process recipe.

12. The system for detecting a semiconductor process of claim 1, wherein the processor is further configured to execute the computer-executable instructions to implement functions of a processing unit of the matching module, the processing unit is configured to suspend use of the production process recipe flow when the production process recipe flow is incorrect or the production process recipe parameters do not meet the preset process recipe parameters.

13. The system for detecting a semiconductor process of claim 1, wherein the processor is further configured to execute the computer-executable instructions to implement functions of a warning unit of the matching module, the warning unit is configured to send early warning information when the production process recipe flow is incorrect or the production process recipe parameters do not meet the preset process recipe parameters.

14. A method for detecting a semiconductor process, comprising:
acquiring a preset process recipe comprising preset process recipe parameters;
acquiring a production process recipe comprising a production process recipe flow and production process recipe parameters; and
determining whether the production process recipe flow is correct, and determining whether the production process recipe parameters meet the preset process recipe parameters.

15. The method for detecting the semiconductor process of claim 14, wherein the determining whether the production process recipe flow is correct comprises:
determining whether the production process recipe flow is correct through a production flow serial number, a path name, and a path serial number, which are contained in a single step in the production process recipe flow,
wherein the production flow serial number is used for indicating an execution sequence of the single step in the production process recipe flow, the path name is used for indicating an execution purpose of the single step in the production process recipe flow, and the path serial number is used for indicating an execution object of the single step in the production process recipe flow.

16. The method for detecting the semiconductor process of claim 15, wherein the determining whether the production process recipe flow is correct through the production flow serial number, the path name, and the path serial number, which are contained in a single step in the production process recipe flow comprises:
alternatively executing the single steps with a same production flow serial number in the production process recipe flow, and sequentially executing the single steps with different production flow serial numbers in the production process recipe flow according to a sequence of the production flow serial numbers; and
determining whether a single step is repeatedly processed or missed in the production process recipe flow based on the execution sequence of the single step in the production process recipe flow.

17. The method for detecting the semiconductor process of claim 16, wherein the determining whether a single step is repeatedly processed or missed in the production process recipe flow comprises: when the single steps with different path names exist in the single steps with a same production flow serial number, determining that a single step is missed; and when the single steps with a same path name exist in the single steps with different production flow serial numbers, determining that a single step is repeatedly processed.

18. The method for detecting the semiconductor process of claim 14, wherein the determining whether the production process recipe parameters meet the preset process recipe parameters comprises: determining whether the production process recipe parameters are in a parameter range of the preset process recipe parameters, and/or wherein the acquiring the preset process recipe comprises: taking a new process recipe as the preset process recipe.

19. The method for detecting the semiconductor process of claim 14, wherein the acquiring the preset process recipe comprises:
acquiring a new process recipe comprising new process recipe parameters and a new process recipe flow;
acquiring a pre-production process recipe comprising pre-production process recipe parameters; and
determining whether the new process recipe flow is correct, and determining whether the new process recipe parameters meet the pre-production process recipe parameters.

20. A non-transitory storage medium having stored thereon instructions that when executed by a processor, implement a method for detecting a semiconductor process, the method comprising:
acquiring a preset process recipe comprising preset process recipe parameters;
acquiring a production process recipe comprising a production process recipe flow and production process recipe parameters; and
determining whether the production process recipe flow is correct, and determining whether the production process recipe parameters meet the preset process recipe parameters.
